(19) United States
(12) Patent Application Publication
(10) Pub. No.: US 2009/0267669 A1
(43) Pub. Date: Oct. 29, 2009

(54) Microwave Generating Apparatus and Microwave Generating Method

(76) Inventor: Shigeru Kasai, Yamanashi-Ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/887,733

(22) PCT Filed: Mar. 31, 2006
(86) PCT No.: PCT/JP2006/306895

§ 371 Date: Jan. 16, 2009

(30) Foreign Application Priority Data
Apr. 4, 2005 (JP) 2005-107953

(51) Int. Cl. H03K 3/00

(52) U.S. Cl. 327/164

(57) ABSTRACT

The present invention is a microwave generating apparatus comprising: a switch signal generator that generates a square wave switch signal having a fundamental frequency of a microwave band; a switching power amplifier that performs a switching power amplification based on the switch signal so as to output an amplified signal; a variable voltage supplier that is capable of variably supplying a driving voltage for amplification to the switching power amplifier; a microwave selector that extracts from the amplified signal a sine wave signal of the same frequency as the fundamental frequency of the switch signal so as to output the same as a microwave; an output signal detector that detects the microwave; and a driving voltage controller that controls the variable voltage supplier based on a result detected by the output signal detector.

### FIELD OF THE INVENTION

The present invention relates to a plasma processing apparatus for processing an object to be processed such as a semiconductor wafer by a plasma generated by a microwave, and a microwave generating apparatus, a microwave supplying apparatus, and a microwave generating method, which are used in the plasma processing apparatus.

### BACKGROUND ART

In order to manufacture a semiconductor integrated circuit, an object to be processed such as a semiconductor wafer is generally subjected to various processes, such as a film-deposition process, a modification process, an oxidation and diffusion process, and an etching process. As to a thin film to be deposited when a semiconductor integrated circuit is manufactured, for the purpose of meeting a requirement of increasing a working speed of a device, there is an ongoing demand for a thin film of a lower dielectric constant to be disposed at a wiring part, and a thin film of a higher dielectric constant to be disposed at a gate part of a transistor and/or a capacitor part of a DRAM. Since these thin films have relatively a poor heat resistance, there is a prevailing tendency to use a plasma processing apparatus capable of performing a predetermined process at relatively a lower temperature, in order to prevent deterioration of properties of these thin films.

Such a plasma processing apparatus is classified into a processing apparatus for generating a plasma by means of a radiofrequency power, and a processing apparatus for generating a plasma by means of a microwave. For example, in the plasma processing apparatus using a microwave, a magnetron provided with a vacuum tube has been conventionally employed to generate a microwave of a high power, such as several hundreds watts, which power is required for a plasma process. Thus, a microwave can be generated with high controllability. The reason for employing a vacuum tube is that there practically exits no semiconductor device that is capable of generating the above-described high power in a microwave band such as some GHz.

However, the magnetron provided with a vacuum tube has a complicated structure, which entails an increased cost for the apparatus. Thus, with a view to reducing the apparatus cost, a microwave generating apparatus has been proposed (see, JP2004-128141A), which apparatus is capable of generating a microwave of a high power, although the microwave generating apparatus does not employ a vacuum tube but has a semiconductor device as a main component.

The microwave generating apparatus is described with reference to FIG. 7. FIG. 7 is a schematic block diagram showing the microwave generating apparatus used in a plasma processing apparatus. As shown in FIG. 7, a sine wave of a microwave band of some GHz is generated by a since wave oscillator 2. After the sine wave is passed through an attenuator 4 having a variable amplification factor, the sine wave is amplified by an A class or AB class amplifier 6. A certain voltage is supplied as a driving voltage to the A/AB class amplifier 6 from a power source 8. The signal amplified by the A/AB class amplifier 6 is distributed into a plurality of signals by a distributor 10. The respective distributed signals are further amplified in parallel by A/AB class semiconductor amplifying devices 12. The respective signals amplified by the A/AB class semiconductor amplifying devices 12 are combined by a combiner 14. Then, a microwave generated by the combination of the signals is propagated through a waveguide 16, passing through a matching circuit 18 to reach an antenna part 20 disposed in a plasma processing vessel. The microwave is radiated by the antenna part 20 into the processing vessel to generate a plasma therein, and thus a semiconductor wafer is plasma-processed by the plasma.

Meanwhile, a power of the microwave output from the combiner 14 is detected by a detector 22, and an amplification factor of the attenuator 4 is adjusted by a controller 24 based on the detected result. In this manner, a microwave of a desired power can be supplied into the processing vessel. The reason for performing an A class or AB class amplification by the semiconductor amplifying device 12 is to make the sine wave to operate even near an upper limit of an operational frequency of the semiconductor amplifying device 12. The reason for using the plurality of semiconductor amplifying devices 12 is that, at this stage, there is no power device of a high power that can rapidly amplify a power of a frequency of a microwave band.

### SUMMARY OF THE INVENTION

In the above conventional microwave generating apparatus, since the semiconductor amplifying device 12 performs an A class or AB class amplifying operation, an operation efficiency is as low as about 25 to 50%, resulting in an increased calorific value.

Further, since the plurality of semiconductor amplifying devices 12 have to be used, the apparatus cost is increased, as well as the apparatus itself is enlarged.

Furthermore, it is considerably difficult to adjust a balance between the operations of the respective semiconductor devices 12 that are electrically connected in parallel.

Taking account of the above problems, the present invention has been made to effectively solve the same. The object of the present invention is to provide a microwave generating apparatus and a microwave generating method, in which a high operation efficiency and reduced dimensions of the apparatus can be achieved, the cost can be lowered, and a need for balance adjusting can be eliminated.

The present invention is a microwave generating apparatus comprising: a switch signal generator that generates a square wave switch signal having a fundamental frequency of a microwave band; a switching power amplifier that performs a switching power amplification based on the switch signal so as to output an amplified signal; a variable voltage supplier that is capable of variably supplying a driving voltage for amplification to the switching power amplifier; a microwave selector that extracts from the amplified signal a sine wave signal of the same frequency as the fundamental frequency of the switch signal so as to output the same as a microwave; an output signal detector that detects the microwave; and a driving voltage controller that controls the variable voltage supplier based on a result detected by the output signal detector.

According to the present invention, the switching power amplifier performs a switching power amplification based on the square wave switch signal having a fundamental frequency of a microwave band. During the amplifying operation, the driving voltage can be variably controlled in a suitable manner. Thus, the microwave selector can extract from the amplified signal a sine wave signal of the same frequency as the fundamental frequency of the switch signal so as to output the same as a desired microwave. Thus, as compared with the conventionally used A class or AB class amplifying operation, an operation efficiency can be improved. In addition, the apparatus itself can be made smaller, a cost can be lowered, and the balance adjustment can be eliminated.

Alternatively, the present invention is a microwave generating apparatus comprising: a switch signal generator that generates a square wave switch signal having a fundamental frequency of a microwave band; a switching power amplifier that performs a switching power amplification based on the switch signal so as to output an amplified signal; a variable voltage supplier that is capable of variably supplying a driving voltage for amplification to the switching power amplifier; a microwave selector that extracts from the amplified signal a sine wave signal of the same frequency as the fundamental frequency of the switch signal so as to output the same as a microwave; a light detector that detects a light emitted from a plasma generated by the microwave; and a driving voltage controller that controls the variable voltage supplier based on a result detected by the light detector.

According to the present invention, the switching power amplifier performs a switching power amplification based on the square wave switch signal having a fundamental frequency of a microwave band. During the amplifying operation, the driving voltage can be variably controlled in a suitable manner. Thus, the microwave selector can extract from the amplified signal a sine wave signal of the same frequency as the fundamental frequency of the switch signal so as to output the same as a desired microwave. Thus, as compared with the conventionally used A class or AB class amplifying operation, an operation efficiency can be improved. In addition, the apparatus itself can be made smaller, a cost can be lowered, and the balance adjustment can be eliminated.

In the above respective inventions, it is preferable that the microwave selector consists of a bandpass filter or a resonator having a high Q value.

In addition, it is preferable that the bandpass filter is one of the filters selected from the group consisting of: a surface acoustic wave filter; a tubular filter; a waveguide filter; a lumped element filter; and a cavity filter.

Alternatively, the present invention is a microwave generating apparatus comprising: a switch signal generator that generates a square wave switch signal having a fundamental frequency of a microwave band; a switching power amplifier that performs a switching power amplification based on the switch signal so as to output an amplified signal; a variable voltage supplier that is capable of variably supplying a driving voltage for amplification to the switching power amplifier; a light detector that detects a light emitted from a plasma generated by the amplified signal; and a driving voltage controller that controls the variable voltage supplier based on a result detected by the light detector.

According to the present invention, the switching power amplifier performs a switching power amplification based on the square wave switch signal having a fundamental frequency of a microwave band. During the amplifying operation, the driving voltage can be variably controlled in a suitable manner. Thus, the amplified signal can be output as a desired microwave. Thus, as compared with the conventionally used A class or AB class amplifying operation, an operation efficiency can be improved. In addition, the apparatus itself can be made smaller, a cost can be lowered, and the balance adjustment can be eliminated.

The switching power amplifier consists of an HEMT and/or an HBT, for example.

In addition, it is preferable that the fundamental frequency is 2.45 GHz.

Alternatively, the present invention is a microwave supplying apparatus comprising: the microwave generating apparatus having any of the features as described above; a matching circuit connected to the microwave generating apparatus via a transmission line; and an antenna part connected to the matching circuit via a transmission line, the antenna part radiating a microwave.

In this case, it is preferable that the antenna part is set to provide a high Q value with respect to a microwave supplied from the microwave generating apparatus.

Alternatively, the present invention is a plasma processing apparatus comprising: a process vessel capable of being evacuated to create a vacuum; a stage disposed in the process vessel, the stage placing thereon an object to be processed; a gas-supplying unit that supplies a predetermined gas into the process vessel; the microwave supplying apparatus having the above feature, the microwave supplying apparatus introducing a microwave into the process vessel to generate a plasma; and an apparatus-controlling unit that controls the microwave supplying apparatus.

Alternatively, the present invention is a microwave generating method for performing a switching power amplification for a square wave switch signal having a fundamental frequency of a microwave band by a driving voltage for amplification to form an amplified signal, and extracting from the amplified signal a sine wave signal of the same frequency as the fundamental frequency of the switch signal to output the same as a microwave, the method comprising the steps of: detecting the microwave; and variably controlling the driving voltage for amplification when the switching power amplification is performed based on the detected value.

### BRIEF DESCRIPTION OF THE DRAWINGS

FIG. 1 is a schematic structural view of a plasma processing apparatus in one embodiment using a microwave generating apparatus according to the present invention;

FIG. 2 is a block diagram of a microwave generating apparatus (and a microwave supplying apparatus) in a first embodiment of the present invention;

FIG. 3 is a circuit principle view of a main part of the microwave generating apparatus shown in FIG. 2;

FIG. 4 is a circuit structural view of an example of a D class amplifier;

FIG. 5 is a block diagram of a microwave generating apparatus in a second embodiment of the present invention;

FIG. 6 is a block diagram of a microwave generating apparatus in a third embodiment of the present invention; and

FIG. 7 is a schematic block diagram of a conventional microwave generating apparatus used in a plasma processing apparatus.

### BEST MODE FOR CARRYING OUT THE INVENTION

Embodiments of a microwave generating apparatus, a microwave supplying apparatus, a plasma processing apparatus, and a microwave generating method, which are according to the present invention, are described below in detail with reference to the attached drawings.

### First Embodiment

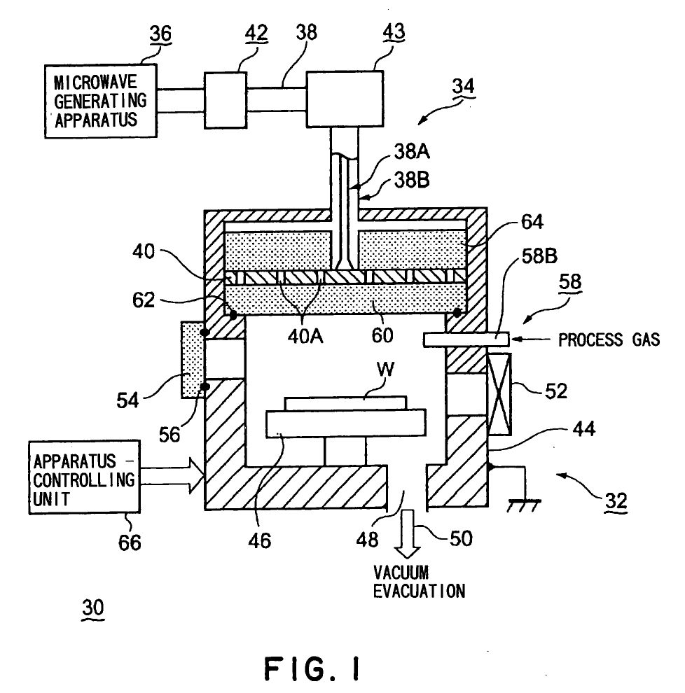

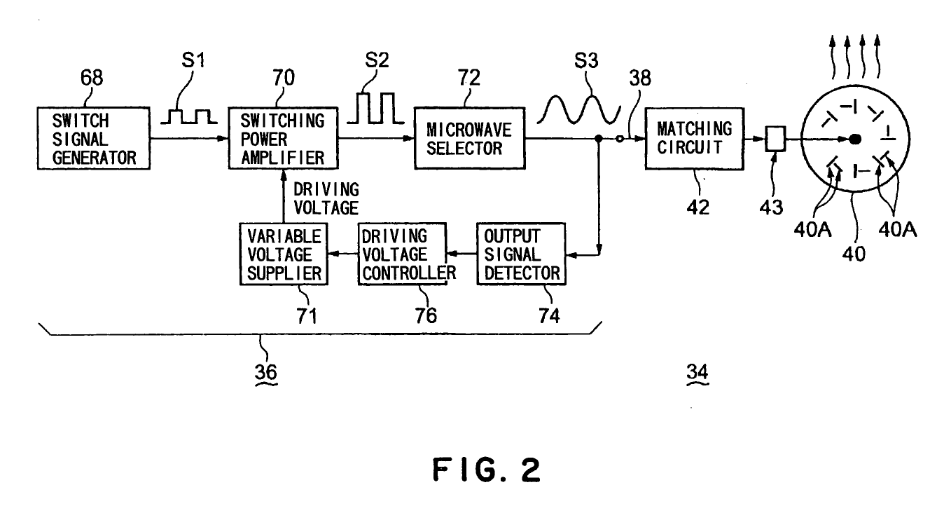

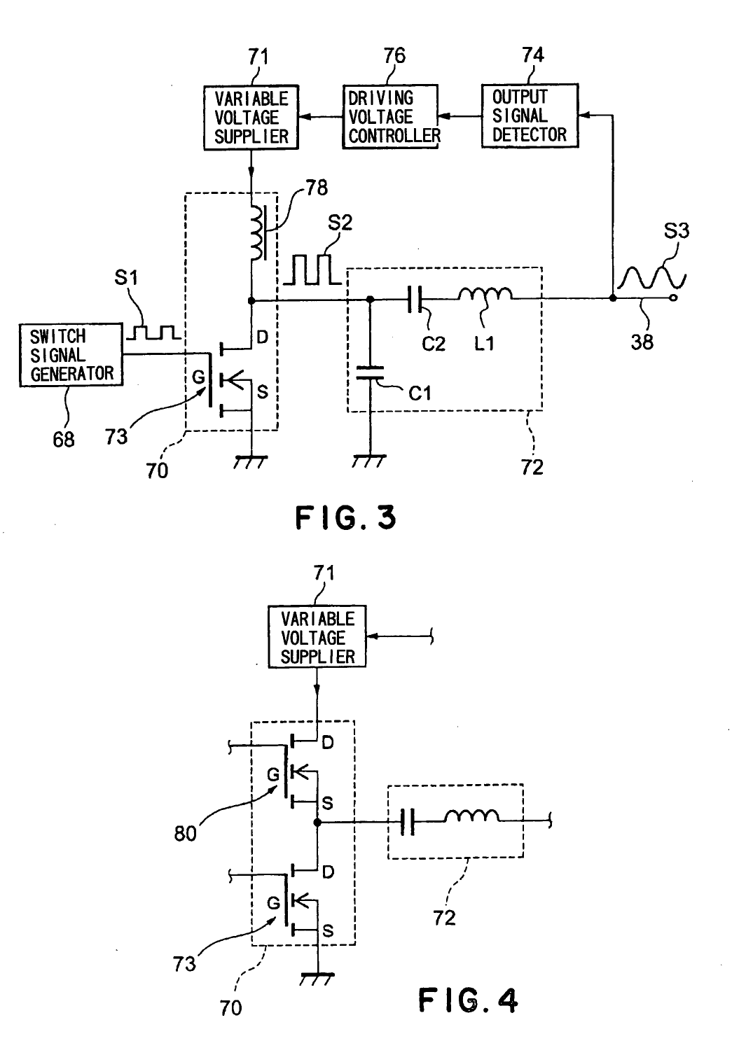

FIG. 1 is a schematic structural view of a plasma processing apparatus in one embodiment using a microwave generating apparatus according to the present invention. FIG. 2 is a block diagram of a microwave generating apparatus (and a microwave supplying apparatus) in a first embodiment of the present invention. FIG. 3 is a circuit principle view of (an example of) a main part of the microwave generating apparatus shown in FIG. 2.

As shown in FIG. 1, a plasma processing apparatus 30 is mainly composed of an apparatus body 32 in which a plasma process is actually performed, and a microwave supplying apparatus 34 for supplying a microwave into the apparatus body 32.

As shown in FIGS. 1 and 2, the microwave supplying apparatus 34 is mainly composed of: a microwave generating apparatus 36; an antenna part 40 connected to the microwave generating apparatus 36 via a coaxial waveguide 38 as a transmission line; and a matching circuit 42 disposed at an intermediate position of the coaxial waveguide 38. A mode converter 43 for converting an oscillation mode of a microwave is disposed in the coaxial waveguide 38 between the matching circuit 42 and the antenna part 40.

The apparatus body 32 is described with reference to FIG. 1. The apparatus body 32 includes a cylindrical processing vessel 44 made of, e.g., anti-corrosion aluminium. In the processing vessel 44, there is disposed a stage 46 standing from a bottom of the vessel. A semiconductor wafer W as an object to be processed is configured to be placed and held on the stage 46. An electrostatic chuck and/or a heater, not shown, may be disposed in the stage 46, if necessary.

An exhaust port 48 is formed in the bottom of the processing vessel 44. To the exhaust port 48, there is connected a vacuum exhaust system 50 having a not-shown pressure control valve and a vacuum pump disposed therein. Thus, an inside of the processing vessel 44 can be evacuated and maintained at a predetermined pressure.

A gate valve 52, which is opened and closed when a wafer W is loaded and unloaded, is formed in a sidewall of the processing vessel 44. An observation window 54 made of, e.g., transparent quartz glass, through which a situation in the vessel can be monitored, is fitted in the sidewall of the processing vessel 44 via a sealing member 56. A gas supplying unit 58 for introducing a required process gas into the processing vessel is disposed in an upper part of the sidewall of the processing vessel 44. Thus, the required process gas can be introduced into the processing vessel 44. Herein, one gas nozzle 58B is disposed as an example of the gas supplying unit 58. However, a plurality of nozzles can be disposed, or a showerhead structure can be employed, according to need.

An opening is formed in a ceiling part of the processing vessel 44. A ceiling plate 60 made of, e.g., quartz glass, which is transparent to a microwave (allows transmittance thereof), is air-tightly fitted in the opening via a sealing member 62. The discoid antenna part 40 of, e.g., a copper plate is disposed on an upper surface of the ceiling plate 60. A number of slots 40A each having an elongated hole shape are formed in the antenna part 40. As described below, a microwave is radiated downward through these slots 40A.

A slow-wave member 64 for shortening a wavelength of a microwave is disposed on the side of an upper surface of the antenna part 40. The slow-wave member 64 is made of, e.g., AlN, Al₂O₃, or the like, and has a predetermined thickness. An inside cable 38A of the coaxial waveguide 38 of the microwave supplying apparatus 34 is connected to a central part of the antenna part 40, and an outer tube 38B of the coaxial waveguide 38 is connected to the sidewall of the vessel and grounded.

A general operation of the plasma processing apparatus 30 (operations of the respective constituent elements), including an operation of the microwave supplying apparatus 34, is controlled by an apparatus-controlling unit 66 formed of a microcomputer, for example.

Next, the microwave generating apparatus 36 is described with reference to FIGS. 2 and 3.

The microwave generating apparatus 36 is mainly composed of: a switch signal generator 68 that generates a square wave switch signal S1; a switching power amplifier 70 that performs a switching power amplification for the switch signal S1 by a driving voltage for amplification so as to output an amplified signal S2; a variable voltage supplier 71 that variably supplies a driving voltage to the switching power amplifier 70; a microwave selector 72 that extracts, from the amplified signal S2 output from the switching power amplifier 70, a sine wave signal S3 of the same frequency as the fundamental frequency of the switch signal S1 so as to output the same as a microwave; an output signal detector 74 that detects an output of the microwave selector 72; and a driving voltage controller 76 formed of, e.g., a microcomputer that controls the variable voltage supplier 71 based on a result detected by the output signal detector 74, i.e., a feedback signal.

Specifically, the switch signal generator 68 outputs the square wave switch signal S1, as described above. The switch signal S1 has a fundamental frequency of a microwave band (about 1 to 300 GHz), such as a fundamental frequency of 2.45 GHz. The switching power amplifier 70 performs a switching power amplification for the switch signal S1. Particularly in the present invention, since a driving voltage for amplification supplied from the variable voltage supplier 71 is variable, a pulse height of the square wave amplified signal S2 to be output can be varied.

In this embodiment, for example, an E class amplifier is used as the switching power amplifier 70. As shown in FIG. 3, the switching power amplifier 70 of the E class amplifier includes, e.g., a GaAs-HEMT (High Electron Mobility Transistor) 73 which operates as a switch. The switch signal S1 is applied to a gate G of the switching power amplifier 70, and a driving voltage supplied from the variable voltage supplier 71 is variably applied to a drain D through a choke coil 78. A source S is grounded. Thus, the square wave amplified signal S2, whose height has been amplified, can be output. In addition to the above GaAs-HEMT, a GaN-HEMT, an SiGe-HBT (Hetero-junction Bipolar Transistor), an InP-HBT, a GaAs-HBT, and so on, can be suitably used as a semiconductor device used in the switching power amplifier 70.

The switching power amplifier 70 is operated under the condition that, when a drain voltage is zero and/or an inclination of a drain voltage is zero, the GaAs-HEMT is turned on. At this time, switching loss can be made minimum, so that a highly efficient operation can be realized.

As shown in FIG. 3, a principle structure of the microwave selector 72 is a series resonant circuit including: a first condenser C1 which is disposed on a position between a connecting point where the choke coil 78 and the drain D are connected to each other, and a grounding point, so as to be arranged in parallel with the GaAs-HEMT; a second condenser C2; and a first coil L1; which are serially connected from the connecting point.

As the microwave selector 72, a resonator having a high Q value or a bandpass filter having a high Q value may be used. As the bandpass filter, it is possible to use a tubular filter, a waveguide filter, a lumped element filter, a cavity filter, (these are trade names of SPECTRUM FSY MICROWAVE INC.), and a surface acoustic filter.

Due to a resonance action or a filtering action of the microwave selector 72 as structured above, the sine wave signal S3 of the same frequency as the fundamental frequency of the switch signal S1 can be output as a microwave. That is to say, a higher harmonic sine signal other than the fundamental wave is cut herein. Then, the microwave obtained here is propagated toward the antenna part 40 through the coaxial waveguide 38.

Although the microwave selector 72 in this embodiment is constituted by the coil and the condensers, the microwave selector 72 may be constituted by a waveguide circuit.

An output value of the microwave is detected by the output signal detector 74. Based on a detected value, the driving voltage controller 76 controls the variable voltage supplier 71, so that a value of the driving voltage to be supplied to the switching voltage amplifier 70 is controlled according to need.

Next, an operation of the plasma processing apparatus 30 as structured above is described below.

A general operation of the plasma processing apparatus 30 is briefly described in the first place. As shown in FIG. 1, a microwave generated by the microwave generating apparatus 36 is supplied through the coaxial waveguide 38 to the flat-plate antenna part 40 disposed at the ceiling part of the processing vessel 44. The microwave is introduced from the antenna part 40 into the processing vessel 44. The inside of the processing vessel 44 is filled with a predetermined process gas, and is maintained at a predetermined vacuum state, so that the process gas is made plasma by the microwave. Thus, a wafer W placed on the stage 46 is subjected to a predetermined plasma process. During this process, impedance matching is performed by the matching circuit 42, in such a manner that a reflected wave from the antenna part 40 becomes zero. As a plasma process, any process using a plasma can be applied, such as a plasma film-deposition process, a plasma etching process, a plasma ashing process, a plasma cleaning process, and so on.

Next, with referent to FIGS. 2 and 3, an operation for supplying a microwave during a plasma process is described. At first, a square wave switch signal S1 having a fundamental frequency of a microwave band of, for example, 2.45 GHz is output from the switch signal generator 68. The switch signal S1 is subjected to a switching power amplification by the switching power amplifier 70 formed of, e.g., an E class amplifier, so that the square wave amplified signal S2 is provided. A driving voltage for this amplification is variably supplied from the variable voltage supplier 71. Owing to a resonance action or a filtering action of the microwave selector 72, the sine wave signal S3 of the same frequency as the fundamental frequency of the switch signal S1 can be output as a microwave from the amplified signal S2.

As is well-known, the square wave amplified signal S2 can be represented by a higher harmonic wave including a fundamental wave which can be expanded by a Fourier series. Thus, by cutting (removing) a higher harmonic wave other than a fundamental wave by means of the microwave selector 72, the sine wave signal S3 can be extracted, as described above. A microwave formed of the sine wave signal S3 is propagated toward the antenna part 40 through the coaxial waveguide 38. A magnitude of the output of the sine wave signal S3 is detected by the output signal detector 74 so as to conduct a feedback control. Based on a detected result, the driving voltage controller 76 controls the variable voltage supplier 71, so that a value of the driving voltage to be supplied to the switching power amplifier 70 is controlled.

In this manner, a power of the microwave to be supplied to the antenna part 40 can be constantly maintained at a certain value. Although about one second is required to conduct the feedback control, since it takes at least, e.g., some seconds for each semiconductor wafer W to be plasma-processed, the feedback control is sufficiently effective.

As described above, while using an E class amplifier, for example, as the switching power amplifier 70 formed of a semiconductor integrated circuit, a driving voltage thereof is variably controlled at the same time. Therefore, it is possible to simplify a structure of the microwave generating apparatus 36 that is capable of outputting a microwave of a high power, and thus an apparatus cost can be saved. Further, an operation efficiency can be significantly improved.

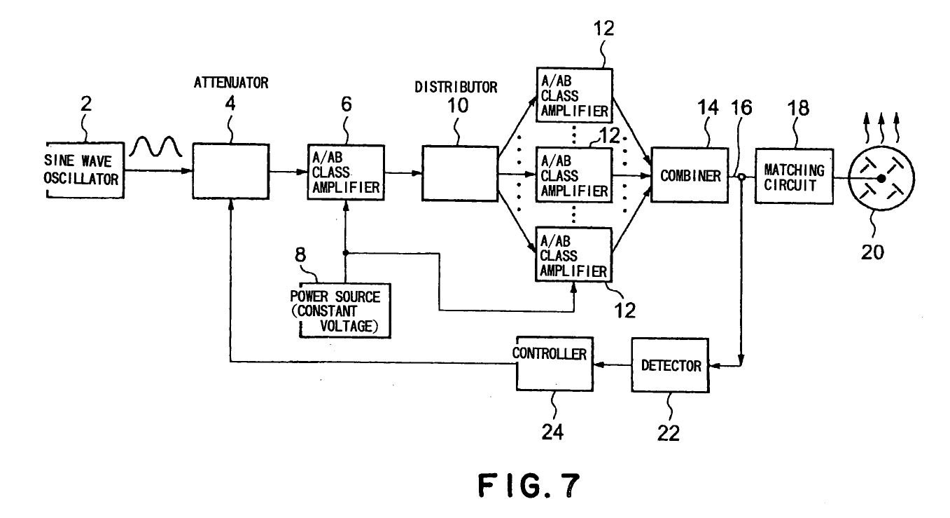

In addition, there is no need for using the plurality of semiconductor amplifying devices 12 which have been described with reference to FIG. 7, and a complicated adjusting operation for combining output signals is no more necessary. Thus, handling of the apparatus can be made easier. When an output of the one microwave generating apparatus 36 is short of a total power required for the plasma processing apparatus, the plurality of microwave generating apparatus 36 may be arranged in parallel. Also in this case, the number of the microwave generating apparatuses can be remarkably decreased as compared with the number of the conventional semiconductor amplifying devices 12.

In this embodiment, as shown in FIG. 3, the E class amplifier is used as the switching power amplifier 70. However, not limited thereto, a D class amplifier may be used, as shown in FIG. 4. In the D class amplifier, in place of the choke coil 78 shown in FIG. 3, there is used a second GaAs-HEMT 80 as a switch device. The GaAs-HEMT 73 and the second GaAs-HEMT 80 are alternately turned on/off. In this case, the first condenser C1 (see, FIG. 3) of the microwave selector 72 may be omitted. Alternatively, in place of the two HEMTs 73 and 80, a combination of an HEMT and an HBT, or a combination of HBTs may be employed.

### Second Embodiment

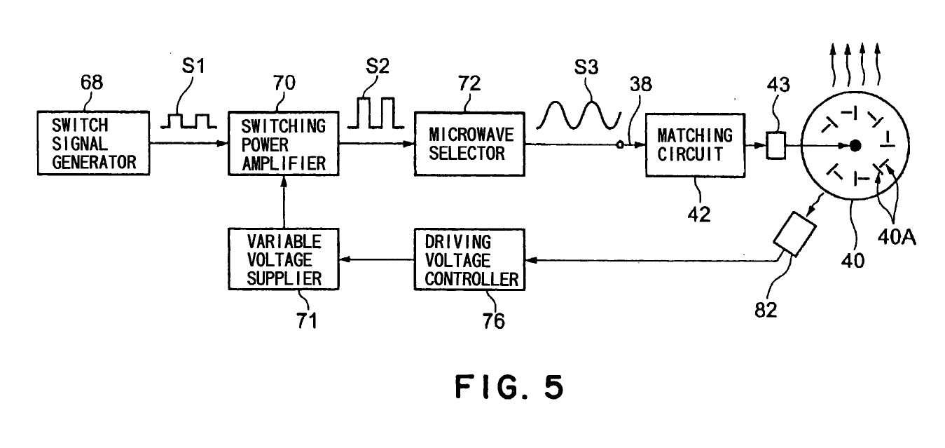

In the first embodiment, the output signal detector 74 for detecting an output of the microwave selector 72 is disposed in order to obtain a feedback signal to be supplied to the driving voltage controller 76. However, in place of the output signal detector 74, there may be employed a light detector that detects a light emitted from a plasma generated in the processing vessel 44. FIG. 5 is a block diagram of a microwave generating apparatus in a second embodiment adopting such a structure. In FIG. 5, the parts having the same structure as the parts shown in FIG. 2 are shown by the same reference numbers, and their detailed description is omitted.

As shown in FIG. 5, in this embodiment, in place of the output signal detector 74 shown in FIG. 2, there is disposed a light detector 82 that detects a light emitted from a plasma generated in a processing vessel 44. The light detector 82 generates a feedback signal. For example, by using an emission spectrometer as the light detector 82, it is possible to detect a light of a specific wavelength whose emission intensity changes depending on a plasma intensity. Thus, a power of the microwave to be supplied can be indirectly detected. Such a light detector 82 is preferably disposed outside an observation window 54 (see, FIG. 1), for example.

### Third Embodiment

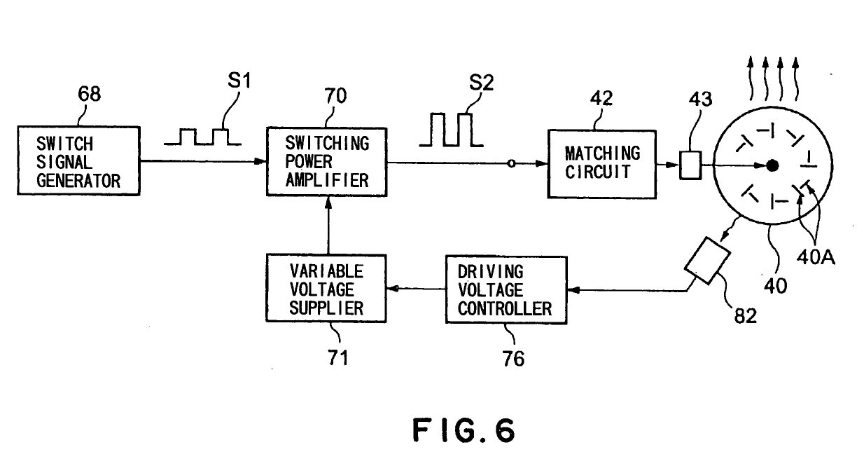

In the first and second embodiments, the sine wave signal S3 output by the microwave selector 72 is supplied to the antenna part 40. However, it is possible to employ a structure in which provision of the microwave selector 72 is omitted, and an output of the switching power amplifier 70 is directly supplied to the antenna part 40. FIG. 6 is a block diagram of a microwave generator in a third embodiment adopting such a structure. In FIG. 6, the parts having the same structure as the parts shown in FIGS. 2 and 5 are shown by the same reference numbers, and their detailed description is omitted.

As shown in FIG. 6, in this embodiment, provision of the microwave selector 72 (see, FIG. 5) is omitted, and a square wave amplified signal S2, which is an output of an switching power amplifier 70 disposed on an upstream side of the microwave selector 72, is propagated to an antenna part 40 through a matching circuit 42 and a mode converter 43. In this case, the antenna part 40 is previously designed to provide a high Q value, and a microwave of the same frequency as a fundamental frequency of a switch signal S1 is supplied from the antenna part 40 into a processing vessel 44. Namely, since the antenna part 40 is designed to provide a high Q value with respect to the fundamental frequency of the switch signal S1, the antenna part 40 itself can additionally have a function of the microwave selector 72. In this case, as a designing guideline, it is preferable that an impedance of the antenna part with respect to a microwave is lowered. According to this embodiment, since provision of the microwave selector 72 can be omitted, the cost required therefor can be deducted from an apparatus cost.

In the above respective embodiments, a semiconductor wafer is used as an object to be processed. However, the object to be processed is not limited to a semiconductor wafer, and the present invention can be applied to a glass substrate, an LCD substrate, a ceramic substrate, and so on.

In addition, not limited to a plasma processing apparatus (semiconductor manufacturing apparatus), the microwave generating apparatus and the microwave supplying apparatus according to the present invention may be applied to another apparatus, such as a microwave oven.

1. A microwave generating apparatus comprising:
a switch signal generator that generates a square wave switch signal having a fundamental frequency of a microwave band;
a switching power amplifier that performs a switching power amplification based on the switch signal so as to output an amplified signal;
a variable voltage supplier that is capable of variably supplying a driving voltage for amplification to the switching power amplifier;
a microwave selector that extracts from the amplified signal a sine wave signal of the same frequency as the fundamental frequency of the switch signal so as to output the same as a microwave;
an output signal detector that detects the microwave; and
a driving voltage controller that controls the variable voltage supplier based on a result detected by the output signal detector.

2. A microwave generating apparatus comprising:
a switch signal generator that generates a square wave switch signal having a fundamental frequency of a microwave band;
a switching power amplifier that performs a switching power amplification based on the switch signal so as to output an amplified signal;
a variable voltage supplier that is capable of variably supplying a driving voltage for amplification to the switching power amplifier;
a microwave selector that extracts from the amplified signal a sine wave signal of the same frequency as the fundamental frequency of the switch signal so as to output the same as a microwave;
a light detector that detects a light emitted from a plasma generated by the microwave; and
a driving voltage controller that controls the variable voltage supplier based on a result detected by the light detector.

3. The microwave generating apparatus according to claim 1, wherein
the microwave selector consists of a bandpass filter or a resonator having a high Q value.

4. The microwave generating apparatus according to claim 3, wherein
the bandpass filter is one of the filters selected from the group consisting of: a surface acoustic wave filter; a tubular filter; a waveguide filter; a lumped element filter; and a cavity filter.

5. A microwave generating apparatus comprising:
a switch signal generator that generates a square wave switch signal having a fundamental frequency of a microwave band;
a switching power amplifier that performs a switching power amplification based on the switch signal so as to output an amplified signal;
a variable voltage supplier that is capable of variably supplying a driving voltage for amplification to the switching power amplifier;
a light detector that detects a light emitted from a plasma generated by the amplified signal; and
a driving voltage controller that controls the variable voltage supplier based on a result detected by the light detector.

6. The microwave generating apparatus according to claim 1, wherein
the switching power amplifier consists of an HEMT and/or an HBT.

7. The microwave generating apparatus according to claim 1, wherein
the fundamental frequency is 2.45 GHz.

8. A microwave supplying apparatus comprising:
the microwave generating apparatus according to claim 1;
a matching circuit connected to the microwave generating apparatus via a transmission line; and
an antenna part connected to the matching circuit via a transmission line, the antenna part radiating a microwave.

9. The microwave supplying apparatus according to claim 8, wherein
the antenna part is set to provide a high Q value with respect to a microwave supplied from the microwave generating apparatus.

10. A plasma processing apparatus comprising:
a process vessel capable of being evacuated to create a vacuum;
a stage disposed in the process vessel, the stage placing thereon an object to be processed;
a gas-supplying unit that supplies a predetermined gas into the process vessel;
the microwave supplying apparatus according to claim 8, the microwave supplying apparatus introducing a microwave into the process vessel to generate a plasma; and
an apparatus-controlling unit that controls the microwave supplying apparatus.

11. A microwave generating method for performing a switching power amplification for a square wave switch signal having a fundamental frequency of a microwave band by a driving voltage for amplification to form an amplified signal, and extracting from the amplified signal a sine wave signal of the same frequency as the fundamental frequency of the switch signal to output the same as a microwave, the method comprising the steps of:
detecting the microwave; and
variably controlling the driving voltage for amplification when the switching power amplification is performed based on the detected value.
